(19) United States
(12) Patent Application Publication
(10) Pub. No.: US 2004/0214432 A1
(43) Pub. Date: Oct. 28, 2004

(54) Thinning of semiconductor wafers

(76) Inventor: Mutsumi Masumoto, Beppu-city (JP)

Correspondence Address: TEXAS INSTRUMENTS INCORPORATED, P O BOX 655474, M/S 3999, DALLAS, TX, 75265

(21) Appl. No.: 10/422,290

(22) Filed: Apr. 24, 2003

(51) Int. Cl. H01L 21/302; H01L 21/461

(52) U.S. Cl. 438/689

(57) ABSTRACT

A method for thinning a semiconductor wafer (201) to less than about 100 μ thickness (208). The wafer has two flat surfaces (206, 207) of a first diameter and a rounded periphery (204a) between the flat surfaces. A generally circular support tape (202) for the wafer is selected having a second diameter. The second diameter is selected to be greater than the first diameter by an amount about twice the length (204a) of the peripheral wafer rounding, as obtained after the thinning step is completed and measured along a radial line. Flat wafer surface 206 is placed on the tape and the wafer is thinned to the intended thickness less than about 100 μ. Specifically, the length (204b) along a radial line may be about 1 mm, making the second diameter about 2 mm larger than the first diameter. Furthermore, the wafer thickness (208) after thinning may specifically be between 10 and 30 μ.

### FIELD OF THE INVENTION

The present invention is related in general to the field of semiconductor devices and more specifically to a method of thinning semiconductor wafers.

### DESCRIPTION OF THE RELATED ART

The semiconductor materials—most frequently silicon, silicon germanium, and gallium arsenide—used in the production of semiconductor devices are single-crystalline materials. Consequently, they break easily under tensile stress and are thus sensitive to mechanical handling. To allow manageable handling and avoid frequent breaking, it is common practice to use relatively thick wafers throughout the numerous front-end processing steps (such as ion implantation, diffusion, oxidation, metallization, chemical and plasma etching, and so forth). As a commonly accepted rule, the wafer thickness has to increase with the larger diameters of the wafers.

After the front-end processing steps (and often the final multiprobe step) have been completed, the wafer thickness has to be reduced by the so-called “back grinding” step in order to permit easy sawing operation for singulating the chips from the wafer. The back grinding operation has been and still is a technically challenging process, suffering from frequent wafer breakage. Consequently, the final wafer thinness has been limited. Further, since the back grinding operation is often performed in one location and the sawing operation in another location (sometimes even in off-shore countries), transportation between these locations demands relatively sturdy wafers.

In the early 1990s, typical silicon wafers of 150 to 200 mm diameter had thicknesses after the thinning process ranging from 350 to 375 μ. In the later 1990s and for the same diameters, a commonly accepted thickness was about 275 μ. In the early 2000s, for silicon wafers of 300 mm diameter, a thickness of 225 μ was implemented in many production lines. The commonly practiced thinning method has been mechanical back-grinding. Wafer breakage during back-grinding and during transportation has limited the wafer thickness, achievable in mass production at acceptable yield, to approximately 100 to 150 μ. Only experimentally has a thickness of about 25 to 50 μ been demonstrated. Alternative thinning methods other than back-grinding have significant drawbacks. For instance, chemical spin etching would require capital investment. Chemical/mechanical wet polishing has low throughput and would also need capital investment. Plasma dry etching has low operational throughput and would also require capital investment.

Consequently, the technical difficulties of breakage and transportation raise the question whether silicon crystallography and mechanical/chemical ablation technology have run into a limit for production that does not allow a significantly lower thickness than about 100 μ. This limit would be in conflict with the emerging market trends for mobile phones and other portable, hand-held and wearable products, which begin to demand device thicknesses based on chips of a thickness less than 50 μ, or even 25 μ. A need has therefore arisen for an efficient, high throughput, high yield but low-cost method of thinning down to a wafer thickness less than 50 and even 25 μ without extraordinary precautions during the thinning process as well as during transportation of the finished material. The innovative thinning method should use the installed equipment base so that no investment in new manufacturing machines is needed. The method should be flexible enough to be applied for different wafer diameters and semiconductor materials, and should achieve improvements towards the goal of process reliability and handling simplification.

### SUMMARY OF THE INVENTION

One embodiment of the invention is a method for thinning a semiconductor wafer to less than about 100 μ thickness, wherein this wafer has two flat surfaces of a first diameter and a rounded periphery between the flat surfaces. In this method, a generally circular support tape for the wafer is selected, where this tape has a second diameter. The second diameter is selected to be greater than the first diameter by an amount about equal to the length of the peripheral wafer rounding as obtained after the thinning step is completed. One of the flat wafer surfaces is placed on the tape and the wafer is thinned to the intended thickness less than about 100 μ. Specifically, the length of the peripheral wafer rounding may be about 1 mm, making the second diameter about 2 mm larger than the first diameter. Furthermore, the wafer thickness after thinning may specifically be between 10 and 30 μ.

In another embodiment of the invention, a method of thinning a semiconductor wafer to a final thickness uses a wafer with first and second flat surfaces of a first diameter and a rounded periphery between these flat surfaces. The wafer is placed on a generally circular support tape such that the first flat surface is adjacent to the tape. The tape has a second diameter which is about equal to the first diameter plus a length, measured along a radial line from the center of the wafer, about equal to twice the length of the rounded periphery at the final wafer thickness. Semiconductor material from the second surface of the wafer is removed until the final thickness is achieved. The tape diameter may be about 2 mm larger than the first diameter.

Embodiments of the present invention are related to thin devices and packages, which are, for example, required in stacks of memory devices and miniaturized products. The ICs for these and similar products can be found in many semiconductor device families such as standard linear and logic products, digital signal processors, microprocessors, wireless devices, and digital and analog devices.

It is a technical advantage of one or more embodiments of the invention that the embodiments can reach the goals of the invention with a low-cost manufacturing method without the cost of equipment changes and new capital investment, by using the installed fabrication equipment base, specifically the established automated mechanically grinding machines. Further, one or more embodiments of the invention can reach the goal of the invention by removing semiconductor material through chemically etching, or chemical/mechanical wet polishing, or plasma dry etching the semiconductor material.

Another advantage which may flow from one or more embodiments of the invention is to produce thin outline devices with packages having interconnection elements including reflowable material, or just with pressure contacts. Other embodiments of thin outline devices include packages with leadframes. Embodiments of the invention generally apply to semiconductor package types such as PDIPs, SOICs, QFPs, SSOPs, TQFPS, TSSOPs, TVSOPs, and Ball Grid Array devices employing leadframes.

The technical advances represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1A is a schematic cross section of a semiconductor wafer having a periphery that includes rounded corners and a straight section.

FIG. 1B is a schematic cross section of a semiconductor wafer having a rounded periphery.

FIG. 2 is a schematic cross section of a portion of a thinned semiconductor wafer on a support tape, illustrating an embodiment of the invention.

FIG. 3 is a schematic cross section of a portion of a thinned semiconductor wafer on a support tape, illustrating another embodiment of the invention.

### DETAILED DESCRIPTION OF THE PREFERRED EMBODIMENTS

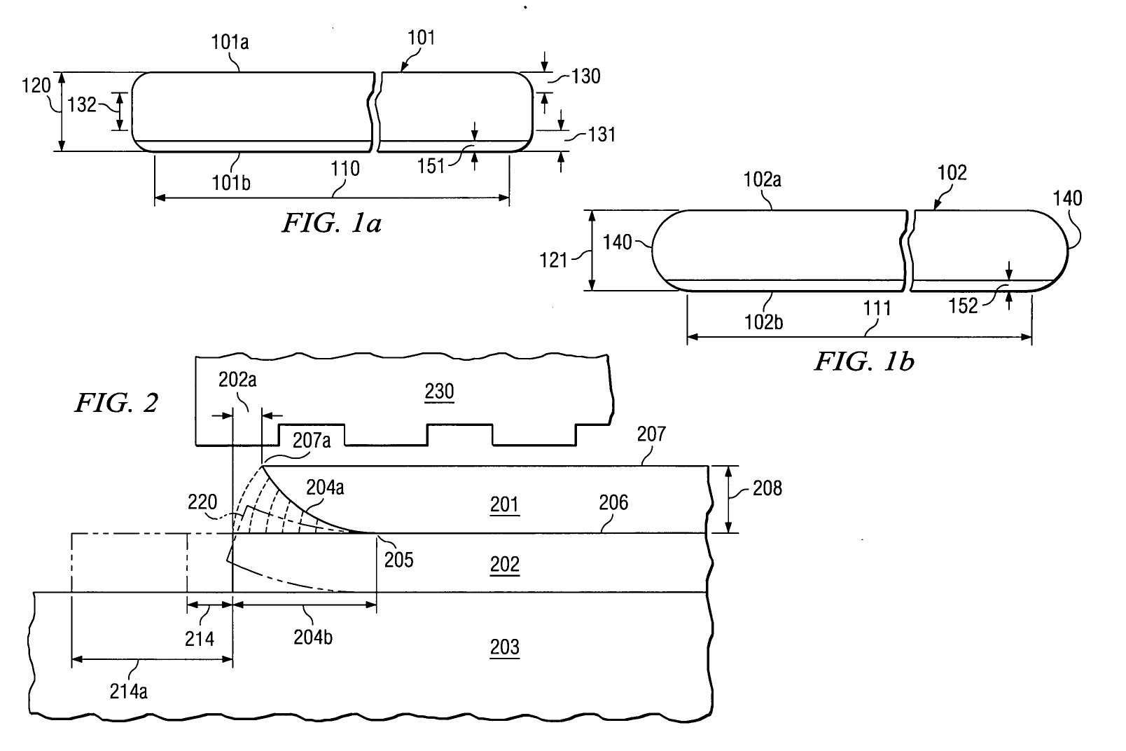

FIGS. 1A and 1B illustrate schematically cross sections of two examples of a rounded periphery of silicon wafers. After completing the process of pulling the single crystal ingot from the semiconductor melt, the generally circular ingot is sawed into individual wafers. The thickness of these wafers is sufficient to avoid damage or breakage of the wafers during the many front-end processing steps for creating the integrated circuits. As an example, silicon wafers of 300 mm diameter typically have a thickness between 700 and 800 μ. Furthermore, in order to avoid chipping of the wafer edges, each wafer is mechanically beveled and/or chemically etched around the periphery to create a rounded, contoured shape of the periphery, as schematically displayed in FIGS. 1A and 1B.

In the example of FIG. 1A, wafer 101 has two flat surfaces 101a and 101b of a first diameter 110 and a thickness 120. The integrated circuitry (IC) will be fabricated into flat surface 101b. For several embodiments of the present invention, the wafer sawed from the ingot has 300 mm diameter, the first diameter 110 is slightly less than 300 mm (about 299 mm), and the thickness 120 is between 700 and 800 μ. In the example of FIG. 1B, wafer 102 also has two flat surfaces 102a and 102b of a first diameter 111 (for example, about 298 mm) and a thickness 121 (for instance between 700 and 800 μ). The IC will be fabricated into surface 102b.

In FIG. 1A, the originally sharp wafer corners have been rounded at portions 130 and 131 to leave a portion 132 of the wafer periphery in the original straight outline. Portions 130, 131 and 132 have approximately the same length. In FIG. 1B, the originally sharp-cornered wafer periphery has been transformed into a rounded periphery 140. The detailed shape of rounded portions 130, 131, and 140 depend on the mechanical beveling and chemical etching technique employed.

After fabricating the IC and completing the final multiprobe test, the IC-bearing surfaces 101b and 102b are protected with a film and the wafers are submitted to the wafer thinning step. Wafer thinning methods include: mechanical back-grinding; chemical spin etching; chemical/mechanical wet polishing; and plasma dry etching. The embodiments of the present invention can be obtained using any of these thinning methods. From the standpoint of operational throughput and low cost, mechanical back-grinding is the preferred method. From the standpoint of mechanical strength of the thinned wafer (low stress, minimal mechanical and thermal damage), chemical etching is the preferred method. From the standpoint of future workability, plasma etching is the preferred method.

For this embodiment, the preferred thinning method is the mechanical back-grinding technology due to its installed equipment base and high wafer throughput. Suitable back-grinding machines are commercially available, for example, from the companies Disco, TSK, and Okamoto, all of Japan.

The remaining wafer thickness after thinning is designated 151 in FIG. 1A, and 152 in FIG. 1B. As can be seen in the schematic figures, the final thickness is a small fraction of the original thickness 120 in FIG. 1A, and 121 in FIG. 1B. The thinned wafer includes the surface 101b in FIG. 1A and 102b in FIG. 1B. These are the surfaces in which the IC is formed.

Throughout the thinning process, the wafer-to-be-thinned is attached to a generally circular support tape. Commercial suppliers of tapes are for instance Lintec and Nitto Denko, both of Japan. The choice of support tape characteristics depends on the thinning method employed. For the back-grinding technique, a preferred tape material is polyethylene with low contamination, high hardness and very little or no water penetration. The tightly controlled thickness is preferably in the range from about 120 to 300 μ. The tape should be rigid to avoid introducing wafer bow. For the chemical etch thinning technique, the tape further needs to be acid resistant. For the plasma thinning technique, the tape needs to be heat resistant.

The schematic cross section of FIG. 2, illustrating a first embodiment of the present invention, shows the final phase of the wafer thinning process in which the back-grinding methodology is the preferred thinning technique. The wafer 201 rests on support tape 202, which, in turn, is positioned on vacuum table (chuck) 203 of the thinning equipment. The edge portion of the wafer includes the remainder 204a of the rounded periphery of the wafer. Since the wafer is generally circular in plain view, length 204a is measured along a radial line from the wafer center. Beginning at point 205, the flat surface 206 of the wafer, which contains the ICs, rests on the flat tape 202. The top surface 207 has been created by the thinning process. The wafer as well as the support tape are generally circular. The diameter of the wafer is measured along the flat surface 206, beginning at point 205.

In the embodiment of FIG. 2, tape 202 extends beyond endpoint 205 of the flat surface 206 of the wafer. As FIG. 2 indicates, the amount of the tape extension is length 204b. In the embodiment of FIG. 2, the length 204b of the tape extension is about equal to the length 204a of the peripheral wafer rounding as obtained in the wafer after the thinning step has been completed. In a preferred embodiment, the length 204b of the tape extension is at least equal to the length 204a of the peripheral wafer rounding as obtained in the wafer after the thinning step has been completed. As long as length 204b is about equal to length 204a, tape 202 cannot extend beyond wafer endpoint 207a, if it would curve upwards along line 204a (as indicated by dashed lines 220 in FIG. 2). The tape 202 is therefore prevented from contacting the grinding tool, which could otherwise result in wafer breakage.

In embodiments with relatively stiff tape materials which have only limited capability of bending, the length 204b may be greater than length 204a by an amount 214; length 214 is approximately 5 to 15% of length 204a. However, length 214 cannot be so large (for example having the size of length 214a) that tape 202 could curve upward and interfere with endpoint 207a of the wafer; such event would likely cause wafer breakage, especially when mechanical grinding equipment is used.

In one embodiment, length 204a as calculated along a radial line of the generally circular wafer is in the range from 0.5 to 1.5 mm. Since tape extension 204b is about equal to length 204a, the diameter of the generally circular tape is from 1.0 to 3.0 mm larger than the wafer diameter (as measured along the flat surface 206). Using this embodiment of the invention for the back-grinding methodology, wafers have routinely been thinned to a thickness 208 less than 50 μ, and frequently to thicknesses 208 between 10 and 30 μ.

It is an additional feature of the embodiment depicted in FIG. 2 that support tape 202 may remain attached to wafer 201 after the thinning process throughout handling and transportation of the wafer to the chip singulation station (wafer sawing operation). For many products, this transportation may be extensive and include overseas shipment. Tape 202 protects wafer 201 against impact, damage, and breakage due to the fact that tape 202 protrudes a small distance 202a beyond the endpoint of the wafer.

The cross section of FIG. 2 depicts schematically a portion 230 of a grinding equipment to exemplify the preferred method of mechanical grinding (back-grinding) for removing semiconductor material from the wafer. As pointed out above, there are several other methods of removing semiconductor material from the wafers. In order to minimize mechanical and thermal damage and stress in the thinning operation, the semiconductor material can be removed by chemical etching. As a combination, chemical/mechanical wet polishing is suitable as a gentle thinning method. For versatility, plasma dry etching is a flexible, although slow, method.

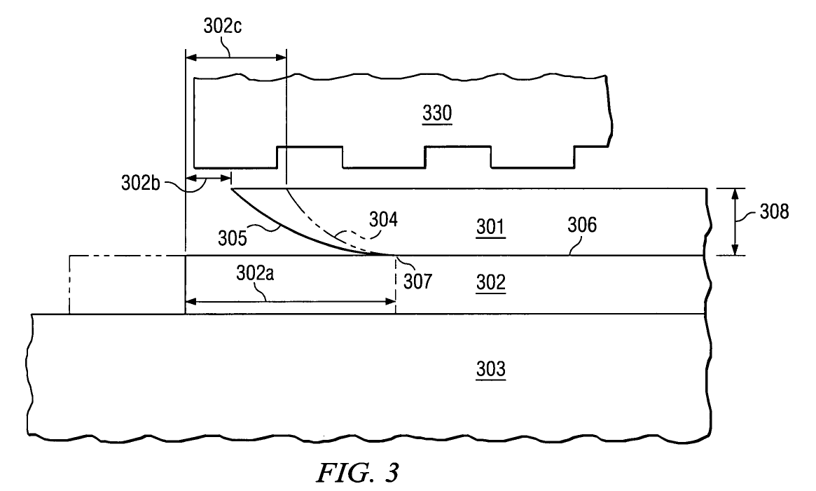

Another embodiment of the present invention is illustrated by the method depicted in FIG. 3. The method is especially suitable for thinning a batch of wafers, where each wafer may have received the rounding of the periphery by a different technique. Examples of wafers having peripheries rounded by different techniques are indicated in FIG. 1A (rounding of regions 130 and 131, while region 132 remains straight) and FIG. 1B (completely rounded profile 140). In FIG. 3, the results of the different rounding techniques are schematically overlaid and indicated on a single wafer 301 by the two peripheral profiles 304 and 305. In this embodiment, a generally circular support tape 302 is selected for a generally circular wafer 301. The flat wafer surface 306, which begins at point 307 and contains the ICs, determines the diameter of the wafer (the start 307 of the flat wafer surface may also vary slightly with each rounding technique). The flat wafer surface 306 rests on the flat tape 302, which, in turn, is positioned on vacuum table (chuck) 303 of the thinning equipment.

As in the embodiment described above, length 302a is selected to match, to the degree possible, the length 304 or 305 of the curved edges of the wafers. The diameter of the generally circular support tape 302 is best selected to be 2.0 mm greater than the diameter of the flat surface of the wafer 301. In yet another embodiment, the diameter of the tape is 1.6 to 2.4 mm greater than the diameter of the wafer 301. With this increased diameter, tape 302 extends beyond the endpoint 307 of the flat wafer portion by a length 302a. For many applications, final thickness 308 is less than 50 μ, in other applications it may be between 10 and 30 μ. Specifically, this embodiment of the invention is suitable to thin wafer to a final thickness of less than 25 μ.

Portion 330 of a grinding equipment indicates schematically a preferred method of removing material from the semiconductor wafer.

It is an additional feature of the embodiments depicted in FIG. 3 that support tape 302 may remain attached to wafer 301 after the thinning process throughout handling and transportation of the wafer to the chip singulation station (wafer sawing operation) . Tape 302 protects wafer 301 against impact, damage, and breakage due to the fact that tape 302 protrudes a small distance 302b (or 302c, respectively) beyond the endpoint of the wafer.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the material of the semiconductor chip may comprise silicon, silicon germanium, gallium arsenide, or any other semiconductor or compound material used in IC manufacturing. It is therefore intended that the appended claims encompass any such modifications or embodiments.

I claim:

1. A method of thinning a semiconductor wafer having first and second flat surfaces of a first diameter and a rounded periphery between said flat surfaces, comprising the steps of:
selecting a generally circular support tape for said wafer, said tape having a second diameter;
selecting said second diameter to be greater than said first diameter by an amount about equal to the length of said peripheral wafer rounding as obtained in said wafer after said thinning step is completed;
placing said first flat wafer surface on said tape; and
removing semiconductor material from said second wafer surface until the intended thickness is achieved.

2. The method according to claim 1 wherein said length of peripheral wafer rounding is calculated along a radial line.

3. The method according to claim 2 wherein said length along a radial line is about 1 mm, making said second diameter about 2 mm larger than said first diameter.

4. The method according to claim 1 wherein said wafer thickness after thinning is less than approximately 100 μ.

5. The method according to claim 1 wherein said wafer thickness after thinning is between 10 and 30 μ.

6. The method according to claim 1 wherein said step of removing semiconductor material comprises mechanically grinding said semiconductor material.

7. The method according to claim 1 wherein said step of removing semiconductor material comprises chemically etching said semiconductor material.

8. The method according to claim 1 wherein said step of removing semiconductor material comprises chemical/mechanical wet polishing said semiconductor material.

9. The method according to claim 1 wherein said step of removing semiconductor material comprises plasma dry etching said semiconductor material.

10. The method according to claim 1 further comprising the step of leaving said support tape combined with said wafer after said completing said thinning steps in order to protect said wafer during subsequent handling and transporting.

11. A method of thinning a semiconductor wafer to a final thickness, said wafer having first and second flat surfaces of a first diameter and a rounded periphery between said flat surfaces, said method comprising the steps of:
placing said wafer on a generally circular support tape such that said first flat surface is adjacent to said tape, said tape having a second diameter wherein said second diameter is about equal to said first diameter plus a length measured along a radial line from the center of said wafer about equal to twice the length of said rounded periphery at said final thickness of said wafer; and
removing semiconductor material from said second surface of said wafer until said final thickness is achieved.

12. The method according to claim 11 wherein said step of placing said wafer on a generally circular support tape comprises placing said wafer on a tape having a diameter about 2 mm larger than said first diameter.

13. A method of thinning a semiconductor wafer having first and second flat surfaces of a first diameter, comprising the steps of:
selecting a generally circular support tape for said wafer, said tape having a second diameter; selecting said second diameter about 2 mm greater than said first diameter;
placing said first flat wafer surface on said tape; and removing semiconductor material from said second wafer surface until the intended thickness is achieved.

14. The method according to claim 13 wherein said wafer thickness after thinning is less than approximately 100 μ.

15. The method according to claim 13 wherein said wafer has a rounded periphery.

16. A method of mechanically grinding a semiconductor wafer to a final thickness, said wafer having first and second flat surfaces of a first diameter and a rounded periphery between said flat surfaces, said method comprising the steps of:
placing said wafer on a generally circular support tape such that said first flat surface is adjacent to said tape, said tape having a second diameter wherein said second diameter is about equal to said first diameter plus a length measured along a radial line from the center of said wafer about equal to twice the length of said rounded periphery at said final thickness of said wafer;
bringing a grinding tool into contact with said second surface of said wafer; and
abrading said second surface of said wafer until said final thickness is achieved.

17. The method according to claim 16 wherein said step of placing said wafer on a generally circular support tape comprises placing said wafer on a tape having a diameter about 2 mm larger than said first diameter.

18. The method according to claim 16 wherein said step of abrading until said final thickness is achieved comprises abrading said wafer until the thickness of said wafer is less than approximately 100 μ.

19. The method according to claim 16 further comprising the step of leaving said support tape combined with said wafer after completing the mechanically grinding step in order to protect said wafer during subsequent handling and transporting.

20. A method of mechanically grinding a semiconductor wafer to a final thickness of less than about 100 μ, said wafer having first and second flat surfaces of a first diameter and a rounded periphery between said flat surfaces, said method comprising the steps of:
placing said wafer on a generally circular support tape such that said first flat surface is adjacent to said tape, said tape having a second diameter about 2 mm larger than said first diameter;
bringing a grinding tool into contact with said second surface of said wafer; and
abrading said second surface of said wafer until said final thickness is achieved.
